(19) United States
(12) Patent Application Publication
(10) Pub. No.: US 2012/0199812 A1
(43) Pub. Date: Aug. 9, 2012

(54) STRAIN TUNABLE SILICON AND GERMANIUM NANOWIRE OPTOELECTRONIC DEVICES

(75) Inventors: Mehmet Onur Baykan, Albany, NY (US); Toshikazu Nishida, Gainesville, FL (US); Scott Emmet Thompson, Gainesville, FL (US)

(73) Assignee: UNIVERSITY OF FLORIDA RESEARCH FOUNDATION, INCORPORATED, Gainesville, FL (US)

(21) Appl. No.: 13/500,681

(22) PCT Filed: Oct. 6, 2010
(86) PCT No.: PCT/US10/51615

§ 371 Date: Apr. 6, 2012

Related U.S. Application Data
(60) Provisional application No. 61/249,571, filed on Oct. 7, 2009.

(51) Int. Cl. H01L 29/66; H01L 29/775; H01L 21/20; H01L 31/0256; H01L 33/04

(52) U.S. Cl. 257/13; 257/28; 257/21; 438/479; 257/20; 257/E21.09; 257/E31.003; 257/E33.005; 257/E29.168; 257/E29.245

(57) ABSTRACT

Silicon, silicon-germanium alloy, and germanium nanowire optoelectronic devices and methods for fabricating the same are provided. According to one embodiment, a P-I-N device is provided that includes a parallel array of intrinsic silicon, silicon-germanium or germanium nanowires located between a p+ contact and an n+ contact. In certain embodiments, the intrinsic silicon and germanium nanowires can be fabricated with diameters of less than 4.9 nm and 19 nm, respectively. In a further embodiment, vertically stacked silicon, silicon-germanium and germanium nanowires can be formed.

### CROSS-REFERENCE TO RELATED APPLICATION

This application claims the benefit of U.S. Provisional Application Ser. No. 61/249,571 filed Oct. 7, 2009, which is hereby incorporated by reference in its entirety, including all figures, tables and drawings.

### BACKGROUND OF THE INVENTION

Nanowires are materials that extend along one dimension with a diameter on the order of a nanometer (1 nm=10⁻⁹ m), and generally less than 100 nm. The electron and hole charge carriers in nanowires are spatially confined (SC) in the quantum-mechanical sense if the nanowire diameter is less than or approximately equal to the Bohr exciton radius of the material. The Bohr exciton radius is different for each material. In silicon, the Bohr exciton radius is 4.9 nm. In contrast, the Bohr exciton radius of germanium is 19 nm. Spatial confinement alters the energy band structure of the semiconductor, which controls the electrical and optical properties of the material.

The semiconductor bandstructure affects the efficiency of electrical-to-optical energy conversion, which determines whether optoelectronic devices are feasible from that semiconductor material. For example, if the bandstructure is direct, electrons and holes can readily recombine to produce a quanta of light, i.e. a photon, with an energy equal to the energy gap (E_{G}) (also referred to as bandgap) of the semiconductor. The wavelength λ of the emitted photon is equal to 1.24/E_{G} in microns when E_{G} is in units of eV. In contrast, if the semiconductor bandstructure is indirect, the conduction band and valence band edges are at different values of the wavevector k. The resulting difficulty of meeting the conservation of momentum requirement when electrons and holes recombine contributes to making indirect semiconductors inefficient at converting electrical energy into light.

Bulk silicon and germanium and silicon-germanium alloys are indirect semiconductors and, hence, have very low electro-optical conversion efficiency. For example, because the bulk silicon energy gap is 1.12 eV, the corresponding photon wavelength is in the infrared band, with a wavelength of λ=1.1 μm. As a point of reference, the visible light wavelength is in the range of 0.4 μm-0.7 μm. Except for low efficiency infrared conventional silicon photonic devices, most photonic crystals used in commercial optoelectronic applications are based on group III-V or II-VI compound or ternary and quaternary alloy semiconductors. These photonic crystals tend to be expensive and difficult to grow on silicon substrates. Accordingly, it has been problematic to integrate these photonic crystals into the mainstream silicon integrated circuit fabrication process due to material incompatibilities.

Commercial visible band photonic devices employ III-V and II-IV group photonic crystals that are either composed of ternary or quaternary alloys of direct and indirect band gap compounds (such as GaAs₁₋ₓPₓ) or indirect band gap materials with isoelectronic traps (such as GaP:N). These crystals inherently have more than an order of magnitude lower photon radiation efficiency compared to crystals with direct band gap.

Related art attempts to make a silicon nanowire light emitting diode (LED) through chemical vapor deposition (CVD) using catalyst growth and silicon tetrachloride (SiCl₄) resulted in thick indirect band gap silicon nanowires, which do not have spatial confinement. Furthermore, the most common catalyst used in bottom-up silicon nanowire growth is gold (Au), which is a deep energy level electron trap in the silicon crystal. In these devices, electrons are likely captured by these traps and recombine with holes through a non photon radiative process. Thus, the efficiency of photon emission was low in the related art gold catalyst grown silicon nanowires.

Other attempts to make silicon nanowire photonic crystals used a template process, where silicon nanowires were grown inside a micromachined porous capsule through Vapor-Liquid-Solid (VLS) or Solid-Liquid-Solid (SLS) methods with the help of a catalyst material. However, the use of a micromachined porous capsule may restrict the practicability of integration with commercial integrated circuit fabrication processes due to its design and process compatibility.

Although research continues to be conducted to fabricate silicon nanowire photonic crystals, integration with mainstream silicon integrated circuit fabrication processes continues to be a road block.

### BRIEF SUMMARY

The intersection of silicon and silicon-germanium (SiGe) CMOS integrated circuit technology and optoelectronic devices is an emerging field. Silicon and emerging SiGe CMOS integrated circuits leverage over a half-century of R&D on silicon microfabrication techniques and constitute a $300+ billion dollar industry providing high performance logic, memory, and linear amplifier products.

The light-emitting optoelectronic (photonic) device has not been in the silicon CMOS technology portfolio due to the indirect bandgap property of bulk silicon, which makes photon emission inefficient. By locally modifying the indirect bandgap of Si to a direct bandgap in a manufacturable way, embodiments of the present invention enable a host of applications ranging from the integration of photonic silicon devices onto the standard CMOS integrated circuit platform for reduced power consumption for increased functionality and performance, as well as new sensors and improved solar cell performance.

Similarly, embodiments of the present invention provide local modification of Ge and SiGe to provide direct bandgap properties of such materials and, thereby, integration of optoelectronic applications into SiGe CMOS integrated circuits.

Designs and fabrication techniques for direct bandgap Si, Ge, and SiGe nanowires are provided that can enable manufacturing, and applications for enhanced CMOS, sensors, and solar cells.

According to one embodiment, a P-I-N device is provided that includes a parallel array of intrinsic silicon nanowires located between a p+ contact and an n+ contact. The intrinsic silicon nanowires can be fabricated with diameters of less than 4.9 nm. According to another embodiment, a parallel array of Ge nanowires located between a p+ contact and an n+ contact can be fabricated to provide a P-I-N device. The intrinsic germanium nanowires can be fabricated with diameters of less than 19 nm. According to yet another embodiment, a parallel array of SiGe nanowires can be fabricated to provide a P-I-N device, where the SiGe nanowires provide the intrinsic semiconductor of the P-I-N device. The nanowires formed of silicon germanium alloys can be fabricated with diameters between those of intrinsic silicon and those of intrinsic germanium.

In a further embodiment, vertically stacked silicon nanowires can be formed. The subject devices can provide photodiodes and LEDs.

A method for fabricating a silicon nanowire optoelectronic device according to one embodiment can include processing a silicon-on-insulator (SOI) wafer. A nanowire region can be fabricated from a thinned region of device layer silicon of the SOI wafer. In one embodiment fins can be patterned on the thinned region of the device layer silicon using silicon etching techniques. In a specific embodiment, e-beam lithography and stress-limited thermal oxidation of fins followed by etching the oxide byproduct away can be performed. In another embodiment, UV photolithography and stress-limited thermal oxidation of fins followed by etching the oxide byproduct away can be performed. In yet another embodiment, UV photolithography, spacer deposition, and stress-limited thermal oxidation of fins followed by etching the oxide byproduct away can be performed.

Methods for fabricating germanium and silicon-germanium nanowire optoelectronic devices can be implemented analogously to that described with respect to the silicon nanowire optoelectronic devices.

Applications of embodiments of the present invention include, but are not limited to an optical clock generator and receiver for low power loss, low skew distribution of clock signals in integrated optoeleetronic silicon (and SiGe) CMOS integrated circuits; optical communication transmitters, receivers, transceivers, repeater nodes, optical mixers, optical couplers and similar devices that are used in fiber optic and other optical communication systems; tunable light emitting diodes (LEDs); LED screens; TVs; LED lightings; LED lamps; tunable laser diodes; photodiodes; light sensors; and solar cells.

Advantageously, embodiments of the present invention enable low cost integration of active photonic devices into silicon (and SiGe) logic integrated circuits.

Certain embodiments of the present invention can incorporate wavelength tuning, which tunes the color of emitted light from silicon nanowires, to provide smooth transition of the emitted light color. This can be accomplished, in one embodiment, by changing the energy gap through built-in microelectromechanical stressors. In another embodiment, this can be accomplished by externally applied mechanical stress. According to one embodiment, the area required for multiple color light emitting active areas can be reduced in a single device, such as a pixel on a TV or screen or lamp.

### BRIEF DESCRIPTION OF THE DRAWINGS

FIG. 1 shows a perspective view of a patterned SOI silicon wafer before thinning the device layer silicon for silicon nanowire optoeleetronic device fabrication in accordance with an embodiment.

FIG. 2 shows a perspective view of a SOI silicon wafer after thinning the device layer silicon for silicon nanowire optoelectronic device fabrication in accordance with an embodiment.

FIG. 3 shows a perspective view of a patterning step for fabricating silicon nanowires in accordance with an embodiment of the present invention.

FIGS. 4A-4C show cross-sectional views through line A-A′ of FIG. 3 for explaining a method for forming silicon nanowires according to one embodiment of the present invention.

FIGS. 5A-5C show cross-sectional views through line A-A′ of FIG. 3 for explaining a method for forming silicon nanowires according to another embodiment of the present invention.

FIGS. 6A-6E show cross-sectional views through line A-A′ of FIG. 3 for explaining a method for forming silicon nanowires according to yet another embodiment of the present invention.

FIGS. 7A-7C show cross-sectional views through line A-A′ of FIG. 3 for explaining a method for forming vertically stacked silicon nanowires according to one embodiment of the present invention.

FIG. 8 shows a perspective view of a silicon nanowire P-I-N diode structure according to an embodiment.

FIG. 9 shows a cross-sectional view of a silicon nanowire P-I-N light-emitting-diode according to an embodiment, and its operation principles.

FIG. 10 shows a cross-sectional view of a silicon nanowire P-I-N photodiode according to an embodiment, and its operation principles.

FIG. 11 shows a cross-sectional view of a vertically stacked silicon nanowire P-I-N coherent light amplifier in accordance with an embodiment of the present invention.

FIG. 12 shows a schematic view of an optical clock distribution system on an integrated circuit that comprises silicon nanowire P-I-N LEDs and photodiodes in accordance with an embodiment of the present invention.

FIG. 13 shows a plot of the bandstructure of an exemplary spatially confined silicon nanowire that exhibits direct bandgap characteristics.

FIG. 14 shows a plot of the bandstructure of <100> direction direct-bandgap silicon nanowire with square cross-section dimensions of 1.5 nm by 1.5 nm according to an embodiment of the present invention.

FIG. 15 shows a plot of the bandstructure of <110> direction direct-bandgap silicon nanowire with square cross-section dimensions of 1.5 nm by 1.5 nm according to an embodiment of the present invention.

FIG. 16 shows a plot of the bandstructure of <100> direction direct-bandgap silicon nanowire with square cross-section dimenstions of 3 nm by 3 nm according to an embodiment of the present invention.

FIG. 17 shows a plot of the bandstructure of <110> direction direct-bandgap silicon nanowire with square cross-section dimensions of 3 nm by 3 nm according to an embodiment of the present invention.

FIG. 18 shows a plot of the bandstructure of <100> direction direct-bandgap silicon nanowire with square cross-section dimensions of 5 nm by 5 nm according to an embodiment of the present invention. FIG. 19 shows a plot of the bandstructure of <110> direction direct-bandgap silicon nanowire with square cross-section dimensions of 5 nm by 5 nm according to an embodiment of the present invention.

FIG. 20 shows a plot of the bandstructure of <100> direction direct-bandgap silicon nanowire with square cross-section dimensions of 7 nm by 7 nm according to an embodiment of the present invention.

FIG. 21 shows a plot of the bandstructure of <100> direction direct-bandgap silicon nanowire with square cross-section dimensions of 7 nm by 7 nm according to an embodiment of the present invention.

FIG. 22 shows plots of the energy band gap of <100> and <110> direction direct-bandgap silicon nanowires under mechanical strain according to an embodiment of the present invention.

FIG. 23 shows plots of the wavelength of photon emission from the band gap of <100> and <110> direction direct-bandgap silicon nanowires under mechanical strain according to an embodiment of the present invention.

### DETAILED DISCLOSURE

Embodiments of the present invention relate to silicon, silicon-germanium, and germanium nanowire optoelectronic devices and methods of manufacturing the same.

According to one embodiment, strain tunable silicon nanowire optoelectronic devices can be fabricated and integrated with commercial integrated circuit fabrication processes. In other embodiments, such optoelectronic devices can be implemented using silicon-germanium alloys and germanium where the larger Bohr exciton radius of germanium enables an indirect-to-direct energy gap transition at a larger dimension on the order of 18 nm.

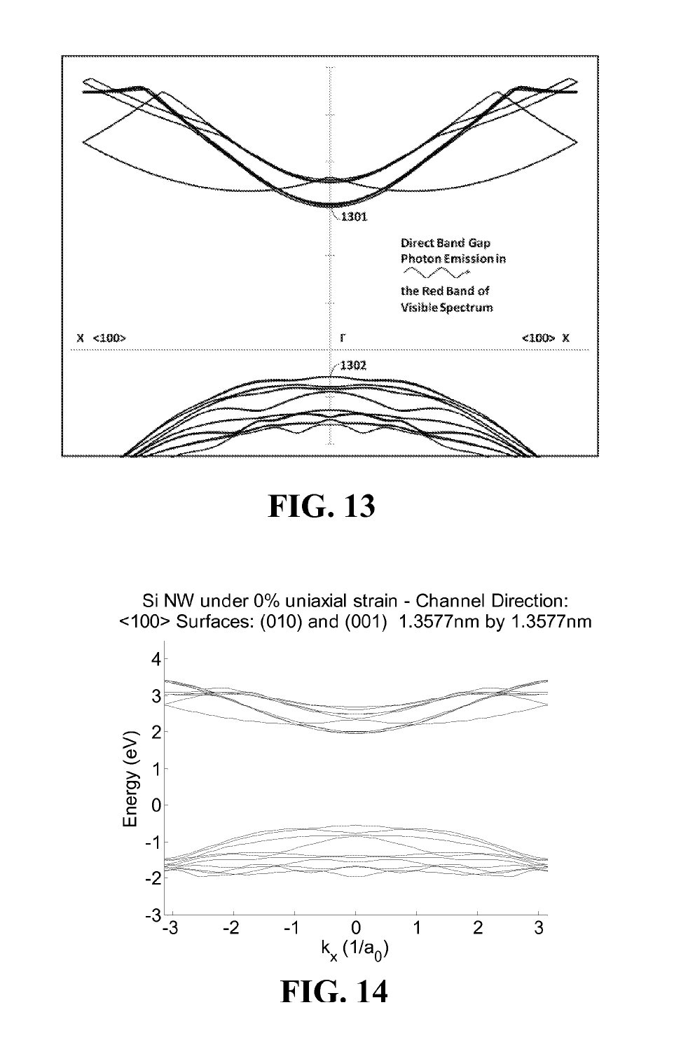

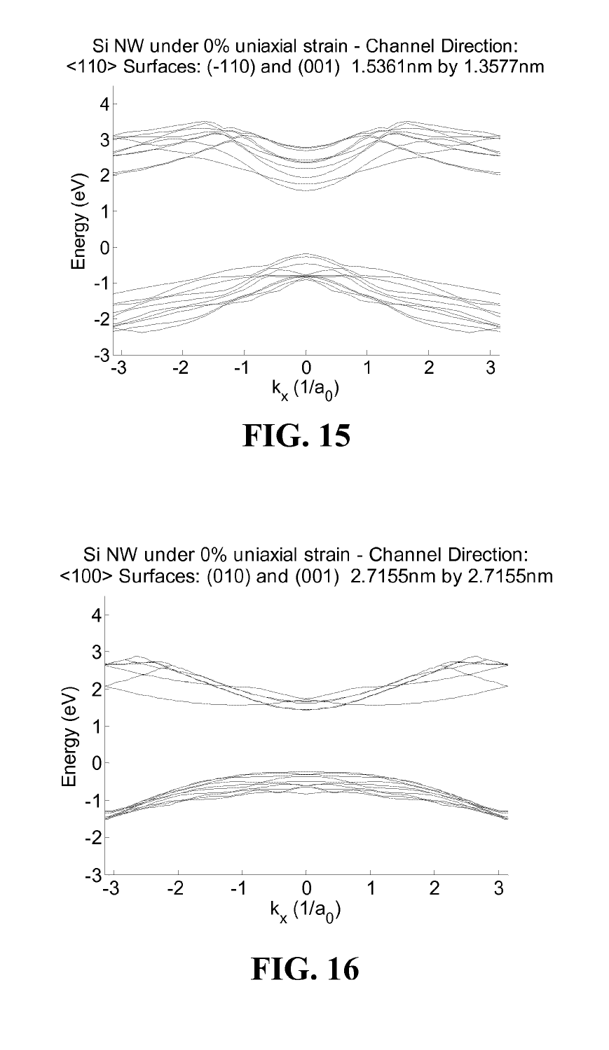

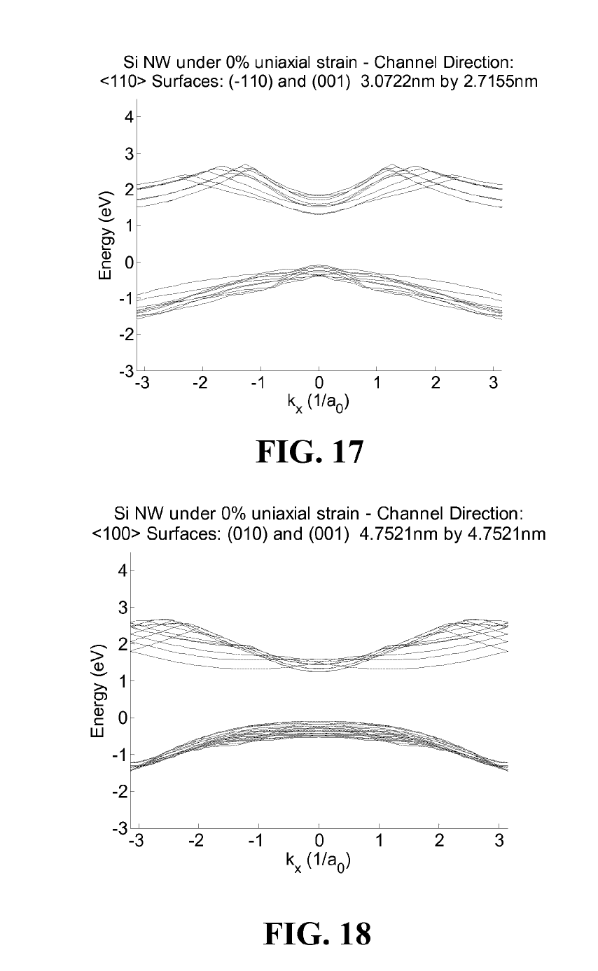

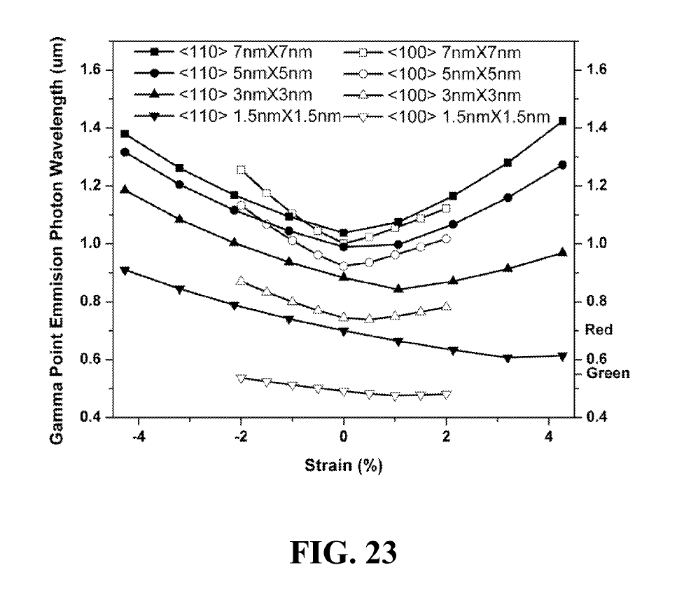

As illustrated by FIGS. 13-23 and described in more detail herein, it is possible to achieve direct band gap attributes in silicon by utilizing spatially confined SiNWs extending along the <100> and <110> crystal directions. The silicon nanowires (SiNWs) fabricated in accordance with certain embodiments of the present invention can be used to provide a direct band gap active photonic region in a device, thereby enabling the direct band gap advantage in efficiency of photon emission. By providing a higher efficiency device, the size, cost, and power consumption of optoelectronic and other photonic devices can be reduced.

According to an embodiment, a device structure is provided, incorporating a parallel array of intrinsic silicon nanowires located between hole-rich P+ and electron-rich N+ contacts. This P+-intrinsic silicon-N+ arrangement is generically referred to as a P-I-N diode when fabricated using conventional planar microfabrication techniques without silicon intrinsic nanowires. Upon forward-bias, holes are injected into the intrinsic silicon nanowires from the P+ contact and electrons are injected into the nanowires from the N+ contact. Electrons and holes recombine as they traverse the length of the nanowires after entering from their respective contacts.

By fabricating silicon nanowire of diameter less than 4.9 nm in accordance with embodiments of the present invention, the silicon nanowire bandstructure is direct, and electron-hole recombination results in efficient photon emission. Methods are provided for manufacturing the silicon nanowire P-I-N diode that can enable practical realization of the device in mass-producible quantities, particularly on the standard silicon CMOS integrated circuit platform. The practical realization of a light emitting silicon nanowire device can be incorporated into silicon integrated circuits. For example, the subject silicon nanowire device can be incorporated in a microprocessor, and can enable an integrated silicon-only optical clock distribution network using a light emitting silicon nanowire P-I-N device operated in forward-bias outputting the clock signal and a light-sensing silicon nanowire device operated in reverse bias with optical waveguides transmitting the emitted light. Strain applied using an internal or external actuator may allow tuning of the emitted light wavelength. For solar cell applications, a direct bandgap silicon nanowire P-I-N device can provide a higher efficiency solar cell since the light-to-electrical energy conversion process is more efficient in a direct semiconductor.

Similarly, for implementations of the P-I-N structure utilizing germanium, by fabricating a nanowire of diameter less than 19 nm in accordance with embodiments of the present invention, the germanium nanowire bandstructure is direct, and electron-hole recombination results in efficient photon emission. Alloys of silicon and germanium enable properties in between that of silicon and germanium.

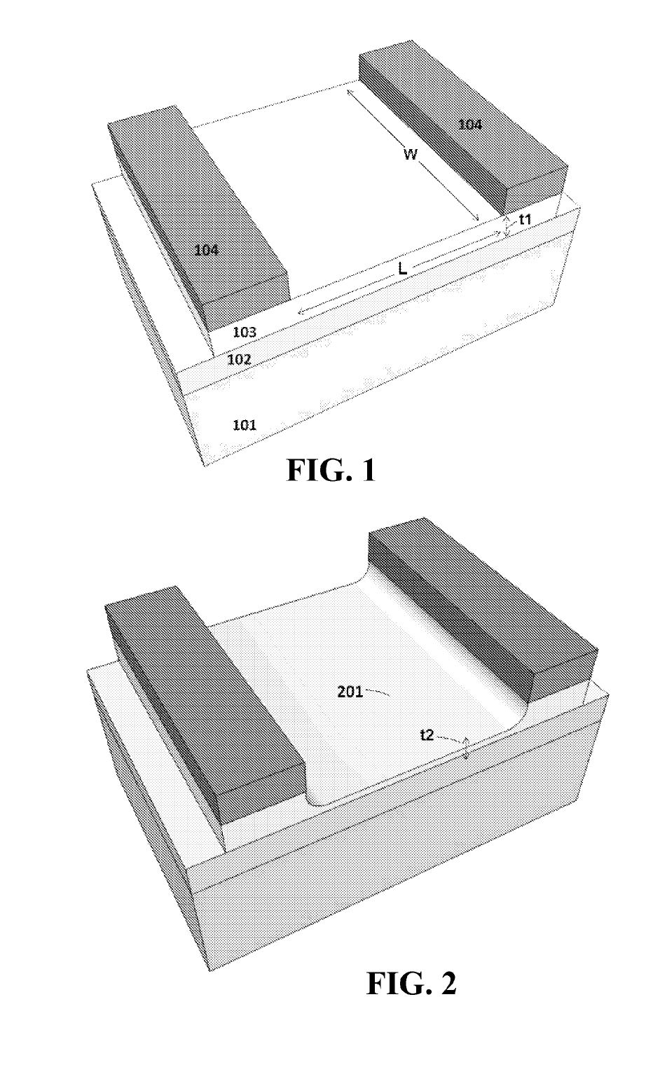

Referring to FIG. 1, silicon nanowires may be prepared by processing a silicon-on-insulator (SOI) wafer that is composed of a handle silicon layer 101, buried oxide 102, and device layer silicon 103. The thickness t1 of the device layer 103 of the SOI wafer may be within, but not limited to, a range of tens of nanometers to micrometers. Therefore, to facilitate the preparation of spatially confined silicon nanowires, an area 201 (see FIG. 2) of the device layer silicon 103 having a design specified width W and length L can be patterned using a pattern mask 104. Then, as shown in FIG. 2, this exposed patterned area 201 is thinned down to a desired thickness t2 of a few to tens of nanometers. The thinning process of silicon device layer may use a combination of methods for anisotropic chemical or mechanical-chemical etching of silicon, as well as growth and etching of silicon dioxide where the oxide growth consumes silicon and the oxide etching removes the oxide byproduct.

For example, in one embodiment, the silicon device layer 103 is covered with a hard mask 104 that exposes the area 201, which will provide an active photonic area, to be thinned. The hard mask 104 can be formed of, for example, SiN. A thermal oxide can be grown on the selected active photonic area 201 and removed, leaving the thinned active device layer 103. The thickness t2 of the silicon device layer 103 after the thinning process depends on the desired application of the silicon nanowire optoelectronic device.

The thinned silicon area may be further patterned into silicon fins by one of the following exemplary methods, but patterning methods are not limited to these as long as a method results in the desired length, height and thickness of the silicon fins.

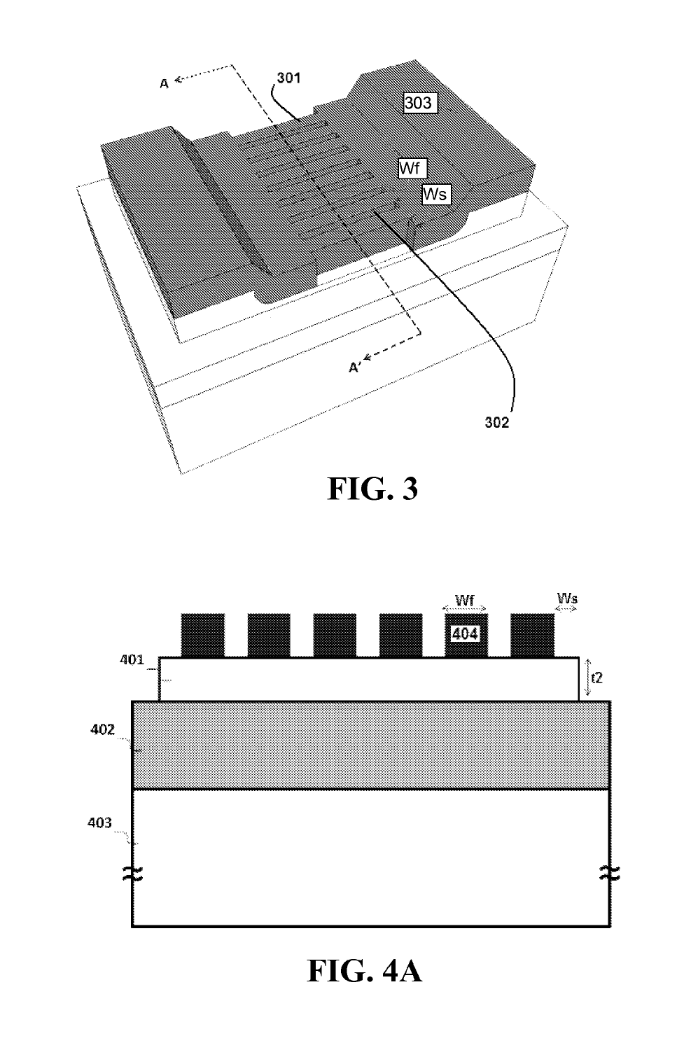

For example, FIG. 3 shows a perspective view of a mask that can be used for patterning of the fins. In FIG. 3, the thinned silicon wafer is covered with a resist material 303, and then this resist material is patterned with mask fins 301 of width Wf and mask slits 302 of width Ws. Using silicon etching techniques, this mask pattern will be transferred onto the underlying thinned silicon device layer.

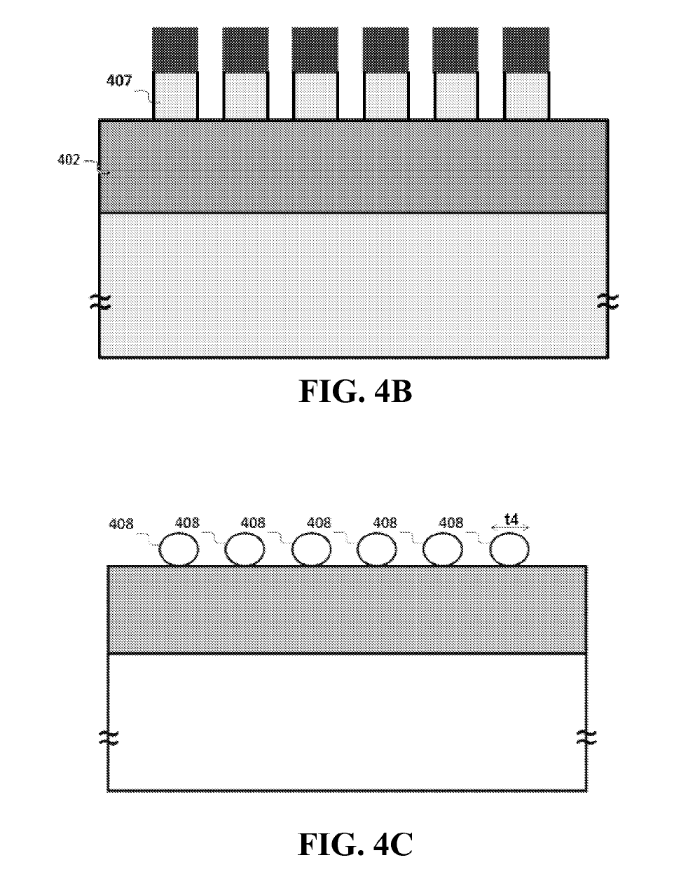

In one embodiment, as shown in FIGS. 4A-4C, a suitable resist or masking material is deposited on the wafer and a few tens of nanometer wide fins are patterned on the mask using electron beam lithography. Referring to FIG. 4A, a cross-sectional view according to one embodiment across line A-A′ of FIG. 3 shows the thinned device layer silicon 401 of height t2, buried oxide 402, handle silicon layer 403, and e-beam patterned mask fins 404 of width Wf and separation Ws. Then, referring to FIG. 4B, anisotropic silicon etch techniques may be used to transfer the mask pattern 404 onto the underlying silicon 401, down to the buried oxide layer 402. The thickness of the resulting silicon fin 407 may be controlled and the surface may be passivated or smoothed by growing thermal silicon dioxide on these fins and etching the grown oxide away by an isotropic SiO₂ etchant, such as hydrofluoric acid (HF). Depending on the oxidation temperature, the viscosity of the grown silicon dioxide changes during the oxidation process, thus altering the final thickness of the remaining silicon core, limited by the stress-dependent oxidation of silicon. The thinning process may be repeated several times to reach a desired thickness for the silicon fin 407. In certain embodiments, before and after the oxidation based thinning process, further surface treatment can be performed including a hydrogen anneal induced silicon migration for resurfacing, reduction of line-edge roughness, and additional thinning. After a predetermined number of repetitions of the thinning and annealing process (required to achieve a particular thickness), silicon nanowires 408 of thickness t4 are formed on the buried oxide 402, as shown in FIG. 4C.

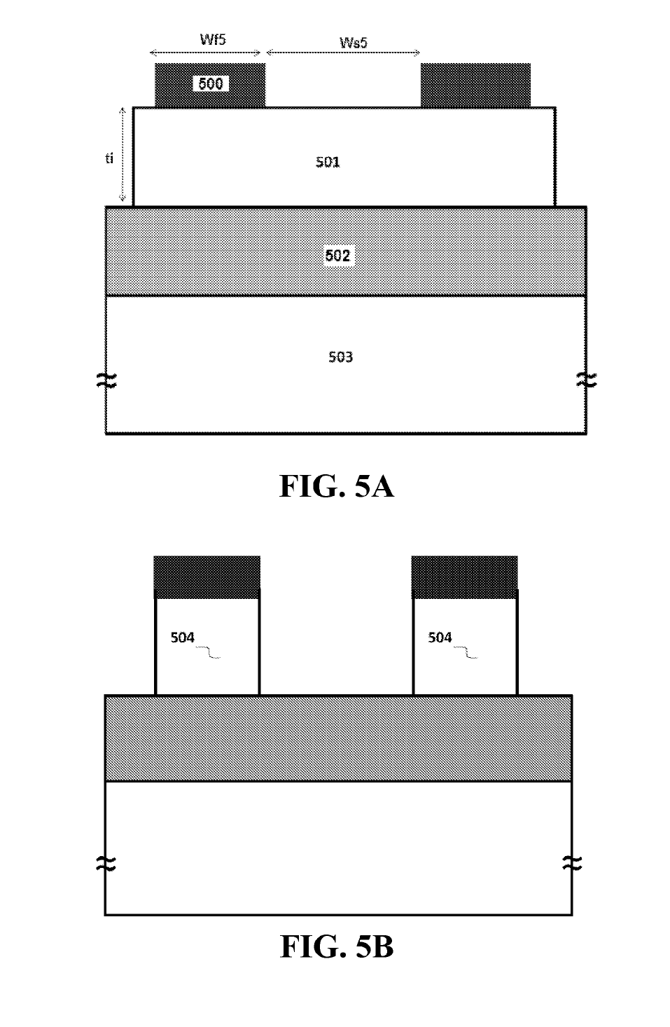

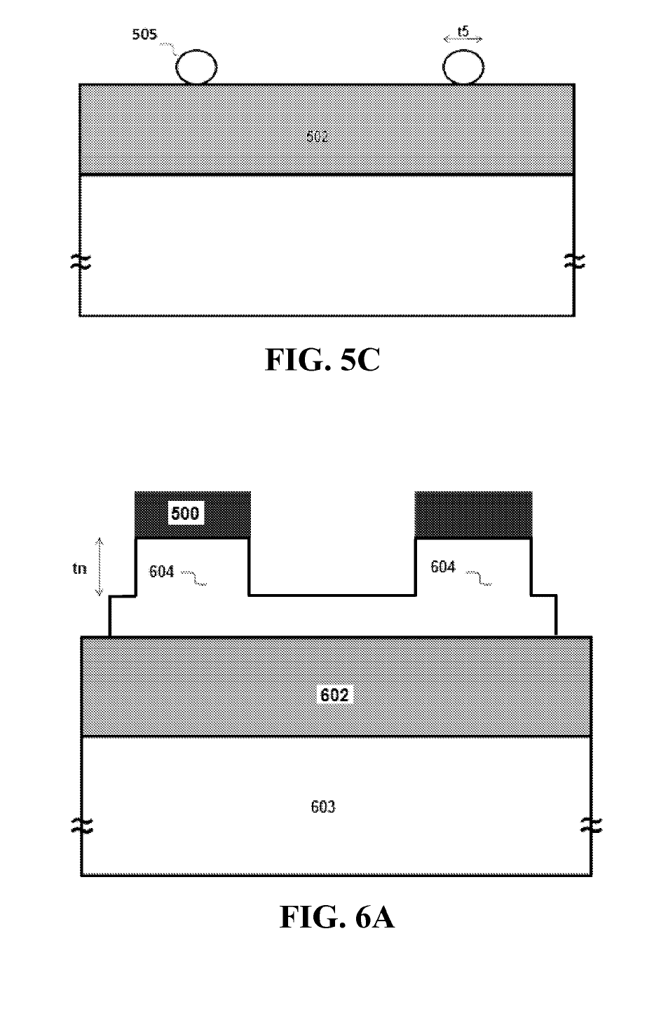

In another embodiment, such as shown in FIGS. 5A-5C, a similar mask pattern with wider mask fins (for example, widths in the 60-100 nm range) can be defined by ultraviolet (UV) photolithography. Referring to FIG. 5A, a cross-sectional view according to one embodiment across line A-A′ of FIG. 3 shows the thinned device layer silicon 501 of height ti, buried oxide 502, handle silicon layer 503, and UV patterned mask 500 of width Wf5 and spacing Ws5. Referring to FIGS. 5A and 5B, the slits in the mask pattern 500 allow anisotropic silicon etching to define silicon fins 504 of desired width Wf5 and length by transferring the pattern on the thinned silicon layer 501. The initial thickness of the silicon layer 501 depends on the desired cross-section specs of the final product. The thickness of the resulting silicon fin 504 may be controlled and the surface may be passivated or smoothed by growing thermal silicon dioxide on these fins and etching the grown oxide away by an isotropic SiO₂ etchant, HF. Depending on the oxidation temperature, the viscosity of the grown silicon dioxide changes during the oxidation process, thus altering the final thickness of the remaining silicon core while limited by the stress-dependent oxidation of silicon. The thinning process may be repeated several times to reach a desired thickness. In certain embodiments, before and after the oxidation based thinning process, further surface treatment can be performed, including a hydrogen anneal induced silicon migration for resurfacing, reduction of line-edge roughness, and additional thinning. After a predetermined number of repetitions of the thinning and annealing process, silicon nanowires 505 of thickness t5 are fowled on the buried oxide 502.

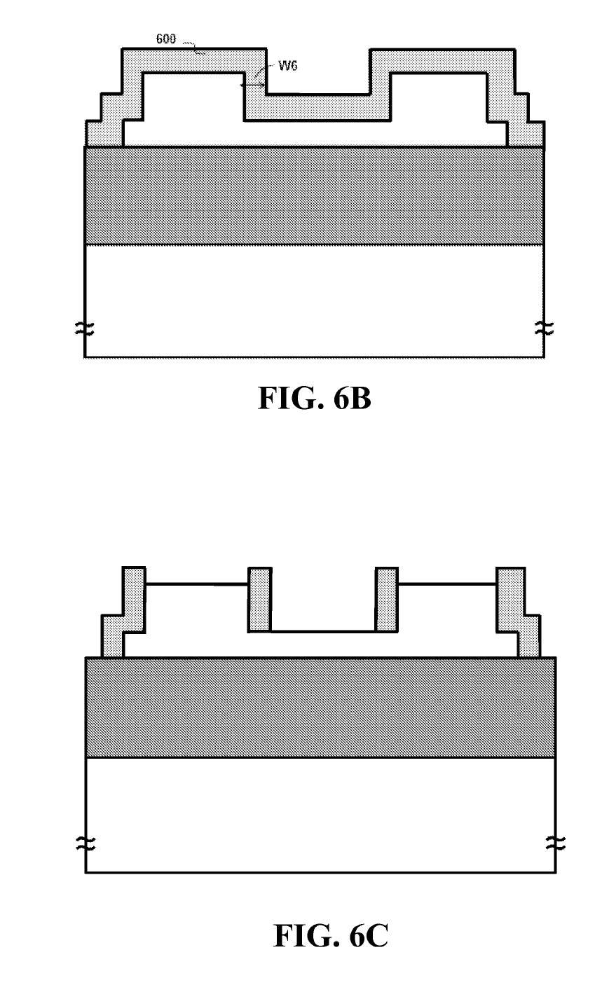

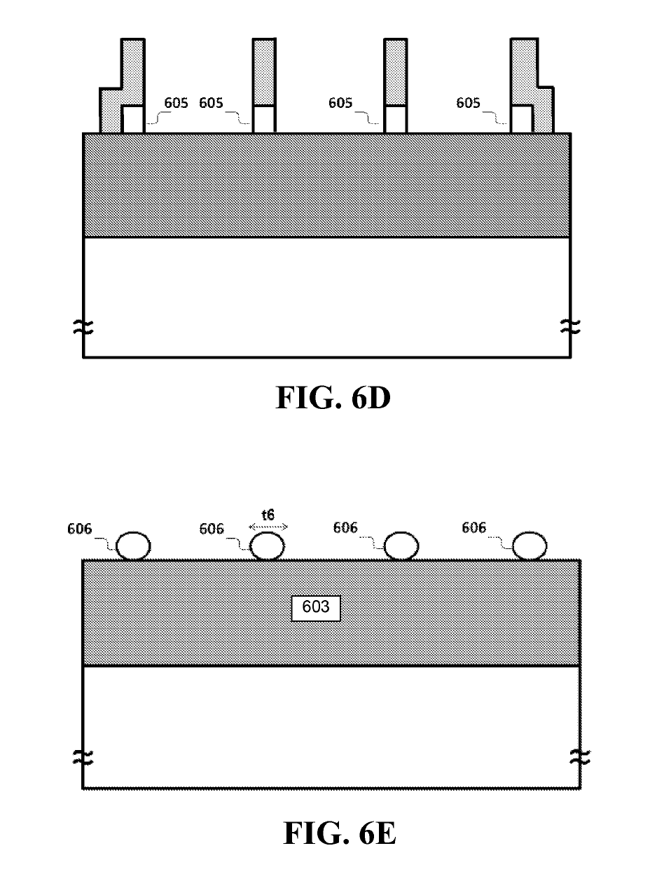

Yet another embodiment is shown in FIGS. 6A-6E, where a spacer method is used to pattern the silicon nanowires. Referring to FIG. 6A, UV photolithography-defined silicon having mask pattern 500 (see also FIG. 5), is etched down for a thickness to similar to the difference between the thickness of the initially thinned silicon t2 and the desired diameter of the final nanowire, defining half fins 604 of width WFS. Then, referring to FIG. 6B, after removing the mask 500, these half fins 604 are covered with another a few nanometer thick material 600, providing a width W6 at a sidewall of the half fins 604. This conformal material 600 is any suitable material capable of withstanding silicon etching processes and is used as a spacer. The conformal material 600 may be SiN or deposited oxide. In certain embodiments, depending on the desired thickness of the final silicon nanowires, the conformal material 600 can be deposited by atomic-layer deposition or a chemical vapor deposition technique. Referring to FIG. 6C, the covered fins may be exposed to reactive ion etching or a similar anisotropic etching method until the spacer is removed from everywhere except for the sidewalls of the silicon fin 604. Since the sidewall spacer thickness can be very thin, for example as thin as 1 nm, it is shown in FIG. 6D that an anisotropic silicon etch may be used to transfer the remaining sidewall spacer pattern onto the underlying silicon layer to form thin order nanometer thick silicon fins 605 of width W6. Reference 602 refers to buried oxide and reference 603 refers to the handle wafer.

The thickness of the resulting silicon fin 605 can be controlled, and the surface may be passivated or smoothed by growing thermal silicon dioxide on the resulting fins 605 and etching the grown oxide away by an isotropic SiO₂ etch. Depending on the oxidation temperature, the viscosity of the grown silicon dioxide changes during the oxidation process, thus altering the final thickness of the remaining silicon core while being limited by stress-dependent oxidation of the silicon. The thinning process may be repeated several times to reach desired thickness. In certain embodiments, before and after the oxidation based thinning process, further surface treatment can be performed, including a hydrogen anneal induced silicon migration for resurfacing, reduction of line-edge roughness, and additional thinning. After a predetermined number of repetitions of the thinning and annealing process, silicon nanowires 606 of thickness t6 are formed on the buried oxide 602 as shown in FIG. 6E.

For a given silicon nanowire thickness, using only UV lithography to pattern the silicon may have the highest number of oxidation/etching process cycles. In contrast, methods using e-beam lithography and/or the spacer (conformal) material can reduce the number of oxidation/etching process cycles because the thickness W6 of the deposited spacer material 600 and the minimum resolvable thickness of the e-beam lithography are thinner than the minimum resolvable thickness of the UV lithography, resulting in a smaller initial thickness and, thus, less repetition of the oxidizing/etching processes to achieve a desired thickness.

The cross-section characteristics of the resulting thin silicon nanowires depend on the height to width ratio of the precursor silicon fins, which may be controlled by the oxidation temperature, oxidation ambient, and oxidation time. By adjusting these parameters, one may fabricate a single silicon nanowire attached to the buried oxide of the SOI wafer or a single suspended silicon nanowire or two vertically stacked silicon nanowires where one is attached to the buried oxide and one is suspended above the attached one.

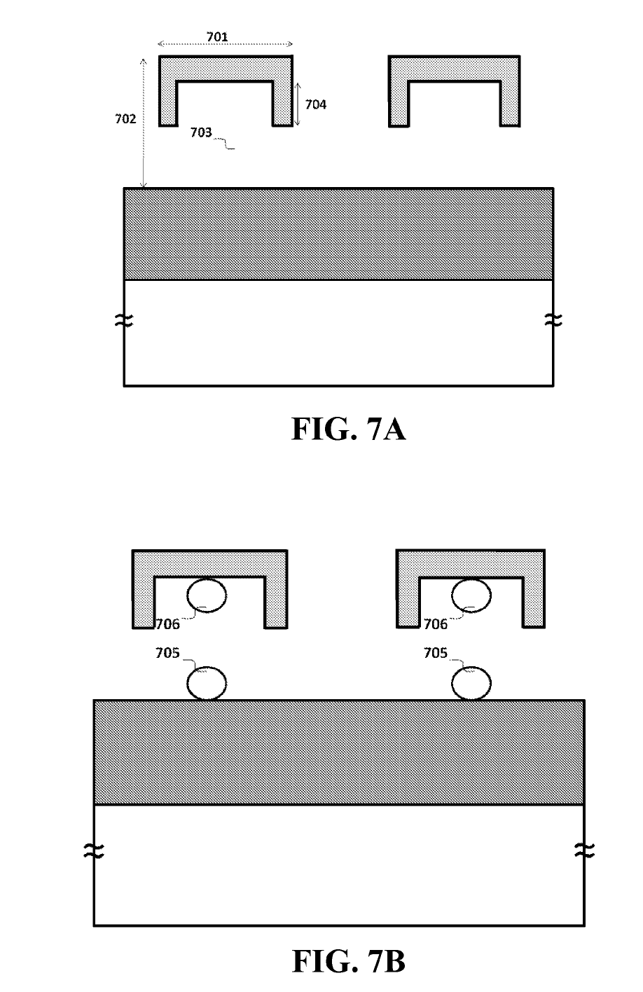

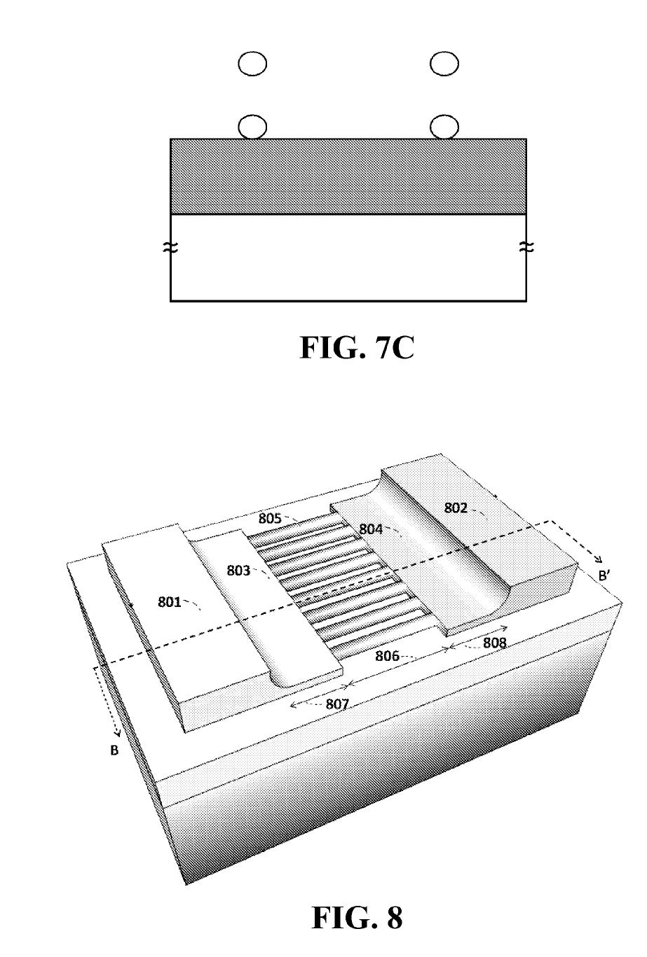

In one embodiment, after the deposition of the spacer material as in FIG. 6B, a patterning and etching process can be performed to form the cross-section shown in FIG. 7A. Depending on the width 701 to height 702 ratio of the fin 703 and the spacer barrier height 704, the thermal oxidation of the fins 703 and etching the SiO₂ results in either a single attached nanowire (such as attached nanowire 705), a suspended nanowire (such as suspended nanowire 706), or a pair of vertically stacked nanowires 705 and 706 as shown in FIG. 7B. The diameters of the final nanowires also depend on the spacer harrier height 704. The diameter of the suspended nanowire 706 tends to be larger than that of the attached nanowire 705, which tends to be smaller as the spacer barrier height 704 increases. As an exemplary embodiment, FIG. 7C shows the cross-section of the pair of vertically stacked silicon nanowires after removing the remaining spacer material.

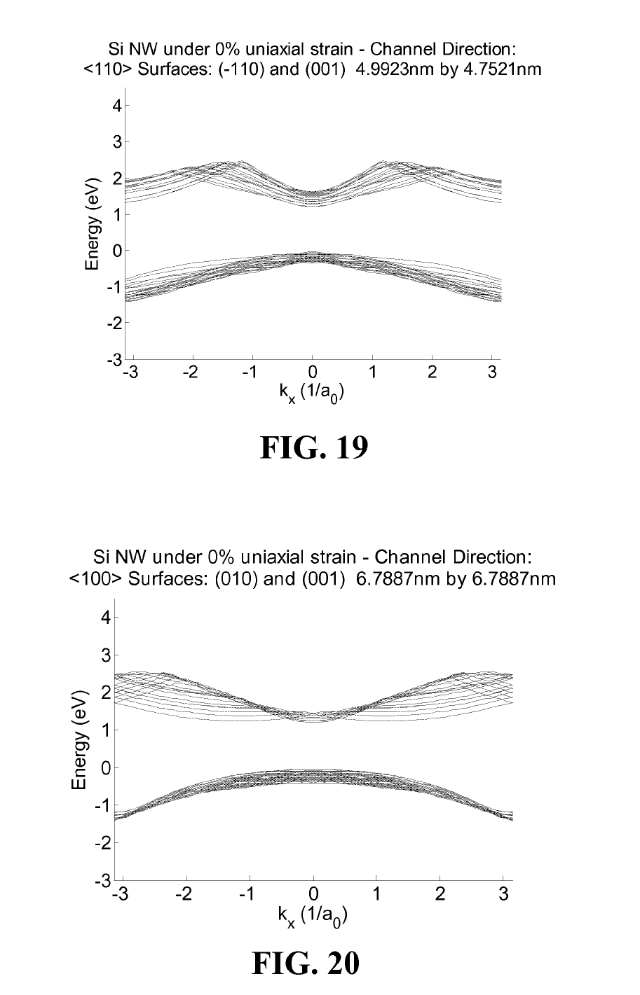

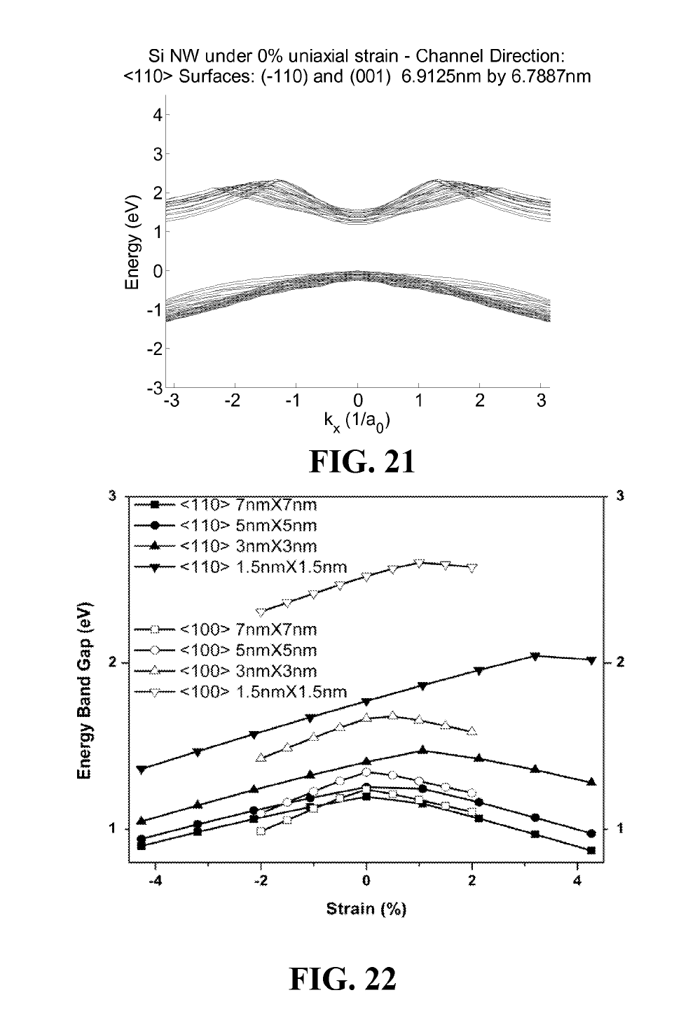

Depending on the initial dimensions of the silicon fin height and width, multiple thermal oxidation and etching of grown SiO₂ may be performed to achieve spatially confined direct band gap silicon nanowires of the desired energy gap. The final fin may have a height and width of around 2 to 5 nm and up to 100 nm before oxidation. A distribution of silicon fin heights and widths can be patterned before oxide growth and etching, in order to ensure a color distribution of emitted light from an ensemble of silicon nanowires. While the color of the light emitted from the silicon nanowires with diameter of 3.5 to 4 nm are within the red band, those from nanowires with a diameter around 1.5 nm are within the blue band. Of course, as shown in more detail in FIGS. 20 and 21, silicon nanowires with diameter of about 7 nm can also provide direct bandgap characteristics.

According to certain embodiments, methods for fabricating germanium and silicon-germanium nanowire optoelectronic devices can be implemented analogously to that described with respect to the silicon nanowire optoelectronic devices. Final diameters of the germanium nanowires can be less than 19 nm, for example 18 nm. Final diameters of the silicon-germanium nanowires can be between the germanium and silicon nanowires, for example, between 5 nm and 18 mm.

FIG. 8 illustrates a general design of a silicon nanowire photonic device. The p-type contact (hole rich), intrinsic silicon nanowire, and n-type contact (electron rich) structure is referred as “silicon nanowire P-I-N diode”. The sources for electrons and holes for an intrinsic silicon nanowire photonic device can be realized in several ways. Referring to FIG. 8, in one embodiment, the p-type contact and n-type contact can be formed by selective doping of each contact by ion implantation followed by a drive-in diffusion process. A group V donor impurity can be implanted for an electron source contact 802 and a group III acceptor impurity can be implanted for a hole source contact 801. According to another embodiment, the n-type (electron source) contact and the p-type (hole source) contact can be formed by selective deposition of in-situ doped polysilicon with a group V donor impurity on the electron source contact 802, and selective deposition of in-situ doped polysilicon with a group III acceptor impurity on the hole source contact 801. Solid source diffusion from the in-situ doped polysilicon to the contacts can then be realized inside a high temperature furnace. In both methods, the dopant atoms tend to diffuse into the thinned silicon layers 803, 804 between each contact 801, 802 and the silicon nanowires 805. The length of the fins is equal to length 806 of the photonic silicon nanowires 805. Therefore, the length L of the thinned silicon area 201 (see FIGS. 1 and 2) should be designed accordingly. Silicon nanowire length 806 is determined by the type of the operation, and may be designed to be either longer or shorter than the recombination length of the electron-hole pairs (EHPs) in the SiNW crystal. However, the remaining thin silicon region 803 and 804 of lengths 807 and 808, respectively, are made much smaller than the recombination length of electron-hole pairs in all cases.

The light emission from the active photonic silicon nanowire crystals may be modified by built-in microelectromechanical stressors or by application of external stress. Depending on the type and the direction of the applied mechanical stress, these stressors may be used to change the wavelength (color), intensity, and efficiency of the emitted light. Mechanical stress can alter the silicon nanowire energy gap, electron and hole effective masses, transit time of carriers inside the nanowire, and the injection efficiency of carriers from the contacts to the nanowire. The mechanical stress may be realized by microelectromechanical systems including, but not limited to, thermal bimorph actuators, thermal membrane deflection, piezoelectric actuation, capacitive, or magnetic actuation. Microelectromechanical stressors can also be built into SiGe and Ge nanowire devices.

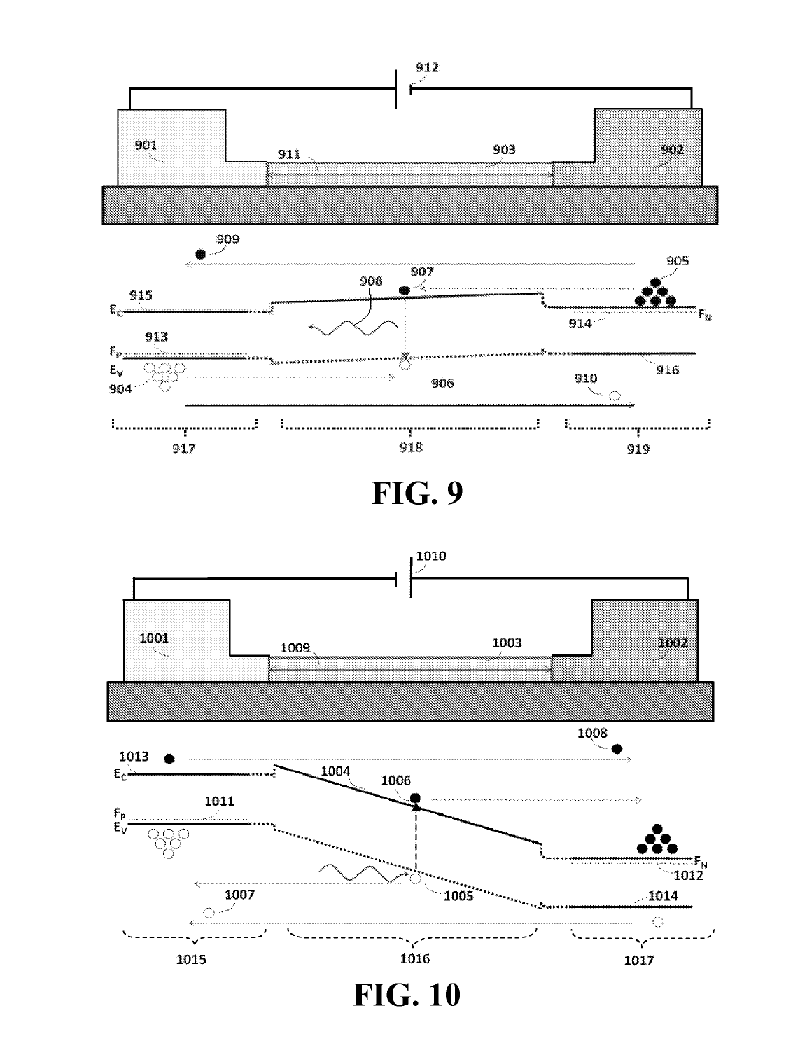

FIG. 9 shows one embodiment of the cross-section along the B-B′ axis of FIG. 8, and illustrates a silicon nanowire light-emitting diode (LED) with its operation principles. In this example embodiment, the electroluminescence (EL) is obtained from silicon nanowires 903 by injecting electrons 905 from the contact 902 doped with group V donor impurity and holes 904 from the contact 901 doped with group III acceptor impurity, and direct recombination of these excess injected carriers inside the intrinsic silicon nanowire 903 crystal. In FIG. 9, the conduction band edge 915 and valence band edge 916 profile of the P contact 917 (901), intrinsic (I) channel 918 and N contact 919 (902) are shown. The external forward bias 912 separates the Fermi energy levels of the P contact 913 and the N contact 914 as shown in the figure. This difference in the Fermi energies causes majority carrier injection into the nanowire channel. During transit of the injected carriers under the applied external bias 912, some electrons 907 and holes 906 may experience spontaneous band-to-band recombination, while giving off a photon 908 with energy approximately equal to the energy band gap of the silicon nanowire 903 crystal. At the same time, some other electrons 909 and some other holes 910 may be swept through the silicon nanowire without undergoing a recombination process. In addition, another fraction of EHPs may be lost in non-radiative recombination processes, such as a trap center or Auger recombination. The length 911 of the silicon nanowire is at least as long as the direct band-to-band recombination length of EHPs in the silicon nanowire. Consequently, the probability of having carriers that are swept through the silicon nanowire (such as electrons 909 and holes 910) is reduced. By forming the length 911 of the silicon nanowire 903 to be at least as long as the direct band-to-band recombination length of EHPs in the silicon nanowire, as many of the injected EHPs (906-907) as possible are used for photon emission 908 in the SiNW active photonic region. This design also helps to increase the ratio of total light power output to total electrical power input. To facilitate photon emission from a region in the middle of the nanowire, the length 911 of the nanowire 903 can be made slightly larger than twice the EHP recombination length in the silicon nanowire.

With decreasing silicon nanowire diameter, the silicon nanowire band gap energy increases and the injection of carriers from the doped contacts into the silicon nanowire becomes more difficult due to the band offsets at the contact junctions. When the silicon nanowire energy gap becomes comparable to twice the energy of the non-degenerately doped contact material energy gap, the bipolar injection of carriers (injection of electrons from N contact and injection of holes from P contact at the same time) to the silicon nanowire decreases even further. For a silicon nanowire P-I-N LED structure that emits photons in the range of 550 nm (˜2.2 eV) or shorter wavelength (higher energy), a gate bias with respect to the P and N contacts is used to create a positive potential between the P-I and I-N contact regions. Thus, a gating structure is used for silicon nanowires that emit light in the green-blue-violet band. In one embodiment, the gate can be realized by a back gate structure that uses a buried oxide 102 (see FIG. 1) as the gate dielectric and back etch thinned handle wafer 101 (see FIG. 1) as the contact of the back gate. In another embodiment, a gate stack that is composed of materials transparent to the emitted light may be used as the top surrounding gate for the nanowires. In yet another embodiment, gating can be used to increase carrier injection efficiency, thus the light intensity, for SiNW P-I-N devices that emit photons in the wavelength range of 550 nm and longer. In another embodiment, a contact region material with a larger energy gap can be used to increase carrier injection efficiency. In such and embodiment, a gating structure can be omitted.

FIG. 10 shows another embodiment of the cross-section along the B-B′ axis of FIG. 8, and illustrates a silicon nanowire P-I-N photodiode with its operation principles. In this example embodiment, under conditions of no illumination, an applied external reverse bias 1010 creates a very low reverse saturation output current by sweeping the minority electrons 1008 and minority holes 1007 through the silicon nanowire 1003.

In FIG. 10, the conduction band edge 1013 and valence band edge 1014 of the P contact 1015, I channel 1016, and N contact 1017 are shown. The external reverse bias 1010 separates the Fermi energy levels of the P contact 1011 (1001) and the N contact 1012 (1002) as shown in the figure. When a photon 1004 with energy equal or larger than the energy gap of the silicon nanowire 1003 is incident on the nanowire, an electron 1006 and a hole 1005 are generated that contribute to the output current. Since the dark current is very low under reverse bias, the photocurrent generated by the photogenerated electrons 1006 and holes 1005 may increase the output current by orders of magnitude. The design of the length of the silicon nanowire 1009 affects the device performance. The reverse bias will sweep out most of the photogenerated carriers before they recombine. The nanowire length is directly proportional to the illumination area of the active photonic layer, thus the longer the nanowire length, the more photons that are captured and the larger the photogenerated current.

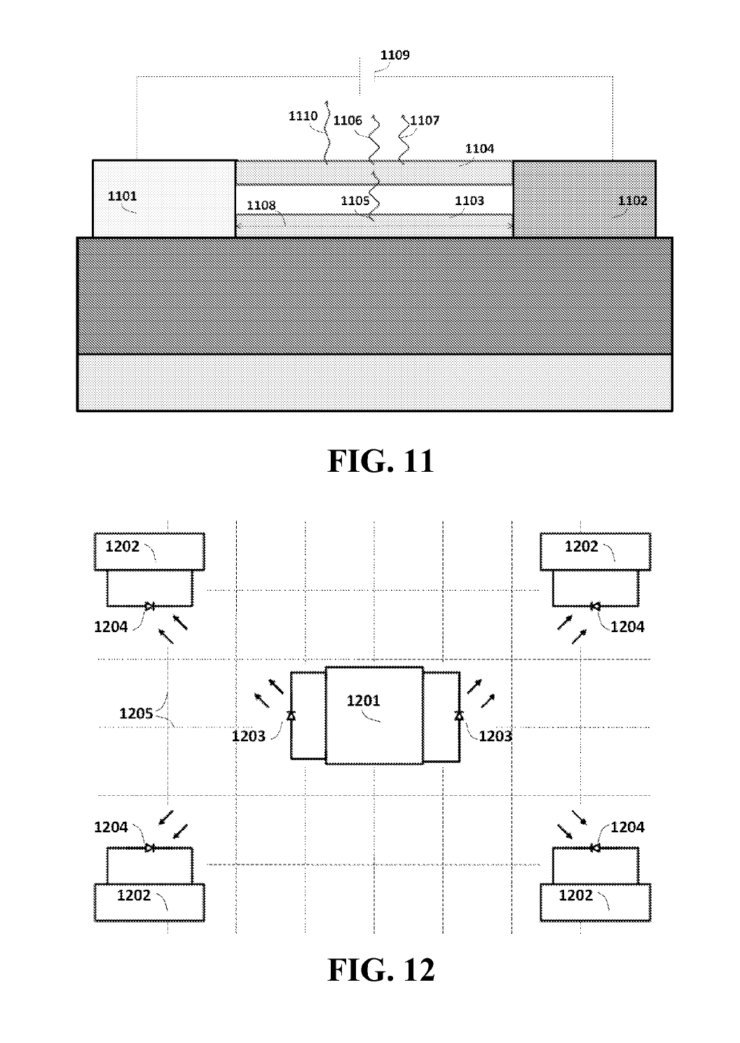

FIG. 11 shows an embodiment of a silicon nanowire optoelectronic device that operates as a light amplifier. The cross-section shown in FIG. 11 is similar to the B-B′ axis of FIG. 8, but illustrates an embodiment having vertically stacked nanowires. Referring to FIG. 11, vertically stacked nanowires 705 and 706 can be prepared as described with respect to FIGS. 7A-7C. The spacer barrier height 704 (see FIG. 7A) can be designed in order to have the same diameter top and bottom nanowires. For embodiments utilizing the stacked nanowires, an initial thinning process of the silicon for the active photon area may be omitted (which would omit the thinned silicon regions 803-804 shown in FIG. 8) because the height 702 of the initial fin 703 pattern is tall for preparation of vertically stacked nanowires. Referring again to FIG. 11, the applied external bias 1109 injects carriers from the contacts 1101-1102 to the bottom 1103 and top 1104 nanowires. The length 1108 of the nanowires can be designed to be longer than the recombination length of the EHPs to increase the emitted light efficiency. The photons 1105, 1106, 1107, and 1110 created by direct recombination of injected carriers in each nanowire may have different wavelength and phase. The photon 1105 created by the bottom nanowire 1103 may trigger a stimulated photon 1107 emission in the top nanowire 1104, and remain as an unperturbed photon 1106. Thus, a coherent photon pair 1106-1107 with incident photon 1105 is generated. Hence this structure may be used as a coherent light amplifier. A stimulated emission in the bottom nanowire triggered by the top nanowire photon 1110 may also exist. However, by adjusting the diameters, thus the energy gap, of the nanowire pairs, one of the nanowires may be designed to be opaque to the photons generated by the other nanowire. This approach can be used to allow amplification of the desired photons and to suppress other (unwanted) photons. Furthermore, this structure can be coupled to a mode selective optical cavity, such as a Fabry-Perot Resonator or a Bragg Resonator, to apply the dual silicon nanowire light amplification of an embodiment of the invention into coherent solid state lasers. Again, in accordance with certain embodiments, the wavelength and intensity of the laser beam can be controlled by the diameter of the light emitting nanowires or built-in stressors.

FIG. 12 shows an illustration of an optical clock distribution in an integrated circuit (IC) that uses silicon nanowire optoelectronic devices in accordance with an embodiment of the invention. The core clock generator of the IC and related driver circuitry 1201 is coupled to silicon nanowire P-I-N LEDs 1203, which can be designed similar to that shown in FIG. 9. The intensity modulated photon radiation from the LEDs 1203 is distributed to the local circuit grid 1205 via a number of possible media. The optical clock signal can be distributed through index-based waveguides, index-based optical fibers, unfocused free-space interconnect, or focused free-space interconnect as a few examples. Silicon nanowire P-I-N photodiodes 1204, configures such as described with respect to FIG. 10, can be used to convert the optical clock signal into a periodic oscillating photogenerated current. The output of the photodiode 1204 may be fed into a series of amplifiers, comparators, buffers if necessary. The optoelectronic clock circuit output can be used to synchronize the local circuits 1202.

Accordingly, in one embodiment, the subject devices can be incorporated for optical clocking. By using CMOS compatible optoelectronic devices fabricated in accordance with embodiments of the present invention, the power consumption dominated by the clock distribution network can lowered. In particular, optical clock distribution that employs silicon nanowire photonic transmitters and receivers may enable low power, low skew global clock distribution in very-large scale integrated circuits. The compatibility issues of non-silicon photonic materials can be avoided by using a silicon based approach in accordance with an embodiment of the present invention.

Another application of a direct bandgap silicon nanowire P-I-N device of an embodiment of the present invention is a high efficiency silicon nanowire solar cell. The direct bandstructure can result in a higher efficiency solar cell since the light-to-electrical energy conversion process is more efficient as well in a direct semiconductor.

Embodiments of the present invention can utilize SiNWs because, although bulk silicon has an indirect bandstructure, spatially confined SiNWs extending along the <100> and <110> crystal directions can have a direct bandstructure. In particular, FIG. 13 shows a plot of energy (eV) vs. normalized wavevector (k) using a silicon nanowire bandstructure simulation for a 2.1 nm thick <100> channel silicon nanowire in accordance with an embodiment of the invention. As shown in FIG. 13, the conduction band edge 1301 and valence band edge 1302 of the 2.1 nm thick <100> channel silicon nanowire show direct bandstructure attributes (direct bandgap). Therefore, the simulations demonstrate that the bandstructure of the spatially confined SiNW is direct. Furthermore, the SiNW energy gap increases as the diameter of the SiNW decreases due to the increase in the strength of the spatial quantum confinement. Thus, thinner silicon nanowires can emit shorter wavelength light potentially in the visible light range or exhibit a blueshift in the photoluminescence (PL) spectrum.

FIGS. 14-23 show additional simulations illustrating the direct band structure of spatially confined silicon nanowires in <100> and <110> directions. The band structures are simulated with a sp³d⁵s* tight-binding method. As shown in FIGS. 14-23, it is possible to provide direct hand gap visible photon emission using silicon, and the direct band gap attributes are modifiable by applying mechanical strain.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. In addition, any elements or limitations of any invention or embodiment thereof disclosed herein can be combined with any and/or all other elements or limitations (individually or in any combination) or any other invention or embodiment thereof disclosed herein, and all such combinations are contemplated with the scope of the invention without limitation thereto.

It should be understood that the examples and embodiments described herein are for illustrative purposes only and that various modifications or changes in light thereof will be suggested to persons skilled in the art and are to be included within the spirit and purview of this application.

What is claimed is:

1. A strain tunable nanowire optical device, comprising:
a first array of silicon, germanium, or silicon-germanium nanowires on a substrate;
a first conductive type contact on the substrate and connected to the first array of silicon, germanium, or silicon-germanium nanowires at one end of the silicon nanowires of the first array;
a second conductive type contact on the substrate and connected to the first array of silicon, germanium, or silicon-germanium nanowires at another end of the silicon, germanium, or silicon-germanium nanowires of the first array.

2. The device according to claim 1, further comprising a gate electrode on the first array of silicon, germanium, or silicon-germanium nanowires.

3. The device according to claim 1, further comprising a second array of silicon, germanium, or silicon-germanium nanowires above the first array of silicon, germanium, or silicon-germanium nanowires, wherein the second array of silicon, germanium, or silicon-germanium nanowires are connected at one end to the first conductive type contact and at another end to the second conductive type contact.

4. The device according to claim 3, wherein the second array of silicon, germanium, or silicon-germanium nanowires are aligned in parallel with the first array of silicon, germanium, or silicon-germanium nanowires between the first conductive type contact and the second conductive type contact.

5. The device according to claim 1, wherein the first array of silicon, germanium, or silicon-germanium nanowires are suspended above the substrate by the first conductive type contact and the second conductive type contact.

6. The device according to claim 1, wherein the silicon, germanium, or silicon-germanium nanowires are silicon nanowires, wherein the silicon nanowires each have a diameter of less than 7 nm.

7. The device according to claim 1, wherein the silicon, germanium, or silicon-germanium nanowires are germanium nanowires, wherein the germanium nanowires each have a diameter of less than 19 nm.

8. The device according to claim 1, wherein the silicon, germanium, or silicon-germanium nanowires are silicon-germanium nanowires, wherein the silicon-germanium nanowires each have a diameter of between 5 nm and 18 nm.

9. The device according to claim 1, wherein at least one silicon, germanium, or silicon-germanium nanowire of the array of silicon, germanium, or silicon-germanium nanowires has a different diameter than others of the array of silicon, germanium, or silicon-germanium nanowires.

10. The device according to claim 1, wherein the silicon, germanium, or silicon-germanium nanowires have a length at least twice the electron-hole pair recombination length of the silicon, germanium, or silicon-germanium nanowires.

11. The device according to claim 1, wherein the silicon, germanium, or silicon-germanium nanowires are silicon nanowires, wherein the substrate comprises a SOI substrate, wherein the first array of silicon nanowires are formed from a silicon device layer of the SOI substrate.

12. The device according to claim 11, wherein the first array of silicon nanowires contact a buried oxide layer of the SOI substrate.

13. The device according to claim 11, further comprising a backgate on the silicon nanowires, wherein the backgate comprises a thinned portion of a handle layer of the SOI substrate, wherein a buried oxide layer of the SOI substrate provides a gate dielectric.

14. The device according to claim 1, wherein the silicon, germanium, or silicon-germanium nanowires are silicon nanowires, wherein the first array of silicon nanowires are formed of intrinsic silicon.

15. The device according to claim 1, wherein the silicon, germanium, or silicon-germanium nanowires are silicon nanowires, wherein the first conductive type contact and the second conductive type contact comprise silicon having dopants implanted or diffused therein.

16. The device according to claim 15, wherein the first conductive type contact and the second conductive type contact further comprise polysilicon on the silicon.

17. The device according to claim 1, wherein the silicon, germanium, or silicon-germanium nanowires are silicon nanowires, wherein the silicon nanowires extend in the <100> direction of the silicon.

18. The device according to claim 1, wherein the silicon, germanium, or silicon-germanium nanowires are silicon nanowires, wherein the silicon nanowires extend in the <110> direction of the silicon.

19. The device according to claim 1, wherein the strain tunable nanowire optical device provides a photodiode.

20. The device according to claim 1, wherein the strain tunable nanowire optical device provides a LED.

21. An optical clock of an integrated circuit comprising at least one strain tunable nanowire optical device according to claim 1.

22. A silicon, germanium, or silicon-germanium nanowire solar cell comprising the strain tunable nanowire optical device according to claim 1.

23. A method of fabricating a strain tunable silicon nanowire optical device, the method comprising:
forming a first array of silicon nanowires from a silicon device layer of a SOI wafer;
forming a first conductive type contact connected to one end of the first array of silicon nanowires; and
forming a second conductive type contact connected to another end of the first array of silicon nanowires.

24. The method according to claim 23, wherein forming the first array of silicon nanowires comprises patterning the silicon device layer.

25. The method according to claim 24, wherein patterning the silicon device layer comprises:
forming a mask pattern by e-beam lithography on the silicon device layer, the mask pattern defining parallel fins on the region defined for the active photonic area along a <100> or <110> crystal direction of the silicon device layer; and
etching the silicon device layer using the mask pattern as an etch mask,
wherein the etching of the silicon device layer exposes a buried oxide layer of the SOI wafer and forms silicon fins.

26. The method according to claim 25, wherein forming the first array of silicon nanowires further comprises reducing the thickness of the silicon fins by performing a process of growing thermal oxide on the silicon fins and removing the grown thermal oxide at least once.

27. The method according to claim 24, wherein patterning the silicon device layer comprises:
forming a mask pattern by ultraviolet lithography on the silicon device layer, the mask pattern defining parallel fins on the region defined for the active photonic area along a <100> or <110> crystal direction of the silicon device layer; and
etching the silicon device layer using the mask pattern as an etch mask.

28. The method according to claim 27, wherein the etching of the silicon device layer exposes a buried oxide layer of the SOI wafer and forms silicon fins.

29. The method according to claim 28, wherein forming the first array of silicon nanowires further comprises reducing the thickness of the silicon fins by performing a process of growing thermal oxide on the silicon fins and removing the grown thermal oxide at least once.

30. The method according to claim 27, wherein the etching of the silicon device layer comprises etching regions of the silicon device layer exposed by the mask pattern to a third thickness of about a desired thickness of one of the silicon nanowires, thereby forming silicon half fins.

31. The method according to claim 30, wherein forming the first array of silicon nanowires further comprises:
removing the mask pattern from the silicon half fins and forming a conformal layer on the silicon half fins;
etching the conformal layer to form spacers at sidewalls of the silicon half fins; and
etching the silicon device layer using the spacers as an etch mask.

32. The method according to claim 31, wherein the etching of the conformal layer removes the conformal layer from the silicon half fins such that the conformal layer remains only at sidewalls of the silicon half fins,
wherein etching the silicon device layer using the spacers as an etch mask forms a silicon nanowire pattern contacting a buried oxide layer of the SOI wafer.

33. The method according to claim 31, wherein etching the conformal layer comprises etching the conformal layer using an etch mask such that the conformal layer remains on top surfaces and sidewalls of the silicon half fins,
wherein etching the silicon device layer using the spacers as an etch mask forms a silicon nanowire pattern suspended over a buried oxide layer of the SOI wafer.

34. The method according to claim 31, further comprising:
forming a second array of silicon nanowires from the silicon device layer, wherein the second array of silicon nanowires are formed above the first array of silicon nanowires and are connected at one end to the first conductive type contact and at another end to the second conductive type contact,
wherein etching the conformal layer comprises etching the conformal layer using an etch mask such that the conformal layer remains on top surfaces and sidewalls of the silicon half fins,
wherein etching the silicon device layer using the spacers as an etch mask forms a first silicon nanowire pattern for the first array of silicon nanowires contacting a buried oxide layer of the SOI wafer and a second silicon nanowire pattern for the second array of silicon nanowires suspended over the first silicon nanowire pattern.

35. The method according to claim 24, wherein forming the first array of silicon nanowires further comprises performing a thinning process to reduce the thickness of the silicon device layer before patterning the silicon device layer, wherein performing the thinning process to reduce the thickness of the silicon device layer comprises:
forming a first mask on the silicon device layer, exposing a region defined for an active photonic area, wherein the silicon device layer has a first thickness;
forming a thermal oxide on the exposed region;
removing the thermal oxide formed on the exposed region, thereby thinning the silicon device layer in the region defined for the active photonic area to a second thickness.

36. The method according to claim 23, wherein forming the first conductive type contact and forming the second conductive type contact comprises:
doping the silicon device layer at a first contact region at the one end of the first array of silicon nanowires and doping a second contact region at the another end of the first array of silicon nanowires.
